(19) United States
(12) Patent Application Publication
(10) Pub. No.: US 2024/0405125 A1
(43) Pub. Date: Dec. 5, 2024

(54) BURIED CHANNEL SEMICONDUCTOR DEVICE INCLUDING ENERGY BARRIER MODULATION REGION(S)

(71) Applicant: TEXAS INSTRUMENTS INCORPORATED, Dallas, TX (US)

(72) Inventors: Jack G. Qian, Plano, TX (US); Doug Weiser, Plano, TX (US); Kemal T. San, Plano, TX (US)

(21) Appl. No.: 18/326,628

(22) Filed: May 31, 2023

(51) Int. Cl. H01L 29/78; H01L 21/265; H01L 29/66

(52) U.S. Cl. CPC H01L 29/7833; H01L 21/26513; H01L 21/26586; H01L 29/66492

(57) ABSTRACT

The present disclosure generally relates to a buried channel semiconductor device that includes one or more energy barrier modulation regions. In an example, a device includes a source/drain region, an energy barrier modulation region, a channel covering surface region, and a gate structure. The source/drain region is in a doped region in a semiconductor substrate that has an upper surface. The energy barrier modulation and channel covering surface regions are in the doped region and at the upper surface. The gate structure is over the upper surface. The energy barrier modulation and channel covering surface regions underlie the gate structure. The energy barrier modulation region is laterally between the source/drain and channel covering surface regions. The doped and energy barrier modulation regions are doped with a first conductivity type, and the source/drain and channel covering surface regions are doped with a second conductivity type opposite from the first conductivity type.

### BACKGROUND

In various semiconductor devices, threshold voltage and leakage current may be significant challenges for specific applications. As devices scale to smaller sizes, threshold voltage and leakage current control may become greater and greater challenges to address. Further, although low threshold voltages may be desirable for increased operating speed of devices, lower threshold voltages may result in increased leakage current.

### SUMMARY

An example described herein is a semiconductor device. The semiconductor device includes a source/drain region, an energy barrier modulation region, a channel covering surface region, and a gate structure. The source/drain region is in a doped region. The doped region is in a semiconductor substrate, and the semiconductor substrate has an upper surface. The doped region is doped with a first conductivity type, and the source/drain region is doped with a second conductivity type opposite from the first conductivity type. The energy barrier modulation region is in the doped region and at the upper surface of the semiconductor substrate. The energy barrier modulation region is doped with the first conductivity type. The channel covering surface region is in the doped region and at the upper surface of the semiconductor substrate. The channel covering surface region is doped with the second conductivity type. The gate structure is over the upper surface. The energy barrier modulation region and the channel covering surface region underlie the gate structure. The energy barrier modulation region is laterally between the source/drain region and the channel covering surface region.

Another example is a method of forming a semiconductor device. A channel covering surface region is formed in a doped region in a semiconductor substrate and at an upper surface of the semiconductor substrate. The doped region is doped with a first conductivity type, and the channel covering surface region is doped with a second conductivity type opposite from the first conductivity type. A gate structure is formed over the upper surface and over the channel covering surface region. An energy barrier modulation region is formed in the doped region and at the upper surface of the semiconductor substrate. Forming the energy barrier modulation region includes implanting a dopant of the first conductivity type in the semiconductor substrate underlying the gate structure. A source/drain region is formed in the doped region. The source/drain region is doped with the second conductivity type. The energy barrier modulation region is laterally between the source/drain region and the channel covering surface region.

A further example is a semiconductor device. The semiconductor device includes a p-type source/drain region, an n-type region, a p-type region, and a gate structure. The p-type source/drain region is in an n-type well in a semiconductor substrate. The semiconductor substrate has an upper surface. The n-type region is in the n-type well and at the upper surface of the semiconductor substrate. The p-type region is in the n-type well and at the upper surface of the semiconductor substrate. The gate structure is over the upper surface. The n-type region and the p-type region underlie the gate structure. The n-type region is laterally between the p-type source/drain region and the p-type region.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a cross-sectional view of a semiconductor device according to some examples.

FIG. 2 is a cross-sectional view of a semiconductor device according to some examples.

FIGS. 3, 4, 5, 6, 7, 8, 9, 10, and 11 are respective cross-sectional views of the semiconductor device of FIG. 1 at various stages of manufacturing according to an example method.

FIG. 12 is a chart illustrating energy barrier heights of different semiconductor devices.

FIG. 13 is a chart illustrating simulated drain current curves for semiconductor devices.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations. In the following discussion, doping concentrations may be described in quantitative and/or qualitative terms, wherein a doping concentration less than 1×10¹⁶ cm⁻³ is lightly doped, a doping concentration between 1×10¹⁶ cm⁻³ and 1×10¹⁸ cm 3 is moderately doped, a doping concentration between 1×10¹⁸ cm⁻³ and 1×10²⁰ cm³ is heavily doped, and a doping concentration above 1×10²⁰ cm⁻³ is very heavily doped. A doping concentration at the boundaries of these ranges may be referred to qualitatively by either term referring to the higher or lower range.

The present disclosure relates generally, but not exclusively, to a buried channel semiconductor device that includes one or more energy barrier modulation regions. Generally, in a buried channel semiconductor device (e.g., a metal-oxide-semiconductor field effect transistor (MOSFET)), a channel region may be formed a depth away from a top surface of a semiconductor substrate on which the gate dielectric layer and gate electrode are formed. By having the channel region at such a depth, charge carriers generally do not interact with the top surface of the semiconductor substrate while being conducted through the channel region, which may result in reduced noise in a signal that results, at least in part, from those conducted charge carriers. However, a threshold voltage of the buried channel device may suffer as a result of the channel region being at this depth. Various examples described herein include a buried channel semiconductor device that includes an energy barrier modulation region between a source or drain region and the channel region, and more specifically, between a lightly doped drain (LDD) region and the channel region. The presence of one or more energy barrier modulation regions may result in an increased threshold voltage of the buried channel semiconductor device, which may further result in decreased leakage current. Other benefits and advantages may be achieved.

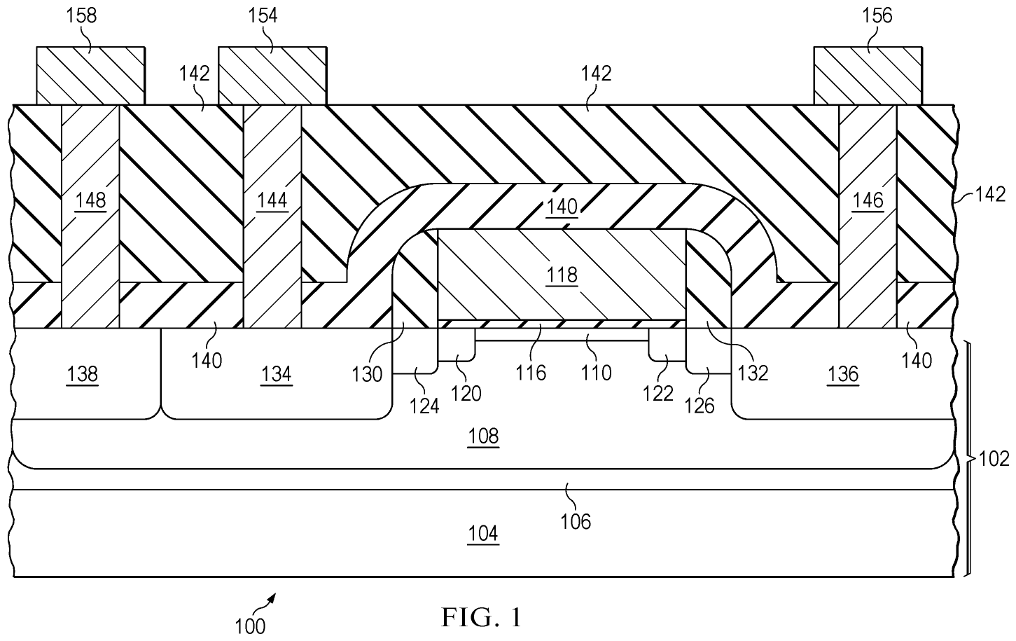

FIG. 1 is a cross-sectional view of a semiconductor device 100 according to some examples. The semiconductor device 100, in this example, is or includes a buried channel MOSFET. The buried channel MOSFET is, in a specific example, a p-type buried channel MOSFET. In other examples, the buried channel MOSFET may be an n-type buried channel MOSFET. As will become apparent, the semiconductor device 100 of FIG. 1 is symmetric with respect to energy barrier modulation regions around a width direction of a channel region of the semiconductor device 100.

The semiconductor device 100 includes a semiconductor substrate 102. The semiconductor substrate 102 has a top major surface in and/or on which devices (e.g., transistors) are generally disposed and formed. The semiconductor substrate 102, in the illustrated example, includes a semiconductor support (or handle) substrate 104 (or handle wafer) and an epitaxial layer 106. The semiconductor support substrate 104 may be a bulk semiconductor substrate, a semiconductor-on-insulator (SOI) substrate, or any other appropriate substrate. The epitaxial layer 106 is epitaxially grown over (e.g., possibly, on) the semiconductor support substrate 104. The epitaxial layer 106 may be or include silicon (Si), silicon germanium (SiGe), gallium arsenide (GaAs), gallium nitride (GaN), the like, or a combination thereof. In some examples, the semiconductor support substrate 104 is or includes a silicon substrate (which may be singulated from a bulk silicon wafer at the conclusion of semiconductor processing), and the epitaxial layer 106 is or includes a layer of silicon. The epitaxial layer 106 is doped with a dopant having a conductivity type. In the illustrated example, the epitaxial layer 106 may be p-doped in situ with a p-type dopant (e.g., boron) at a concentration in a range from about 1×10¹⁴ cm⁻³ to about 5×10¹⁵ cm⁻³, e.g., lightly doped.

In some examples, the epitaxial layer 106 may be omitted, and a semiconductor material of the semiconductor substrate 102 (e.g., in or on which devices are formed) may be or include silicon (Si), silicon germanium (SiGe), gallium arsenide (GaAs), the like, or a combination thereof. In such examples, a well may be implanted in the semiconductor substrate 102 extending from a top major surface of the semiconductor substrate 102 to a depth. The well may be doped, such as by implantation, with a dopant of a conductivity type and to a concentration described with respect to the epitaxial layer 106.

A doped well 108 is disposed in the semiconductor substrate 102 (e.g., in the epitaxial layer 106, as illustrated). The doped well 108 is doped with a dopant that has a conductivity type that is counter to (e.g., opposite from) the conductivity type of the dopant with which the epitaxial layer 106 is doped. In the p-type buried channel MOSFET example, the doped well 108 may be an n-well doped with an n-type dopant at a concentration in a range from about 1×10¹⁵ cm⁻³ to about 5×10¹⁷ cm⁻³, e.g., lightly to moderately doped. In other examples, the doped well 108 may be omitted, such as for an n-type buried channel MOSFET. Any subsequently described doped region or structure that is described as being doped with a dopant of a given conductivity type for a p-type buried channel MOSFET, the region or structure may be doped with a dopant of a conductivity type that is counter to the given conductivity type to implement an n-type buried channel MOSFET.

A channel covering surface region 110 is disposed in the semiconductor substrate 102, and more specifically, in the doped well 108 in the semiconductor substrate 102. The channel covering surface region 110 extends from the top major surface of the semiconductor substrate 102 into a depth in the doped well 108. In some examples, the channel covering surface region 110 extends to a depth of 100 Angstrom (Å) or more, and more specifically, in a range from 200 Å to 300 Å, from the top major surface of the semiconductor substrate 102. The channel covering surface region 110 is doped with a dopant that has a conductivity type that is counter to the conductivity type of the dopant with which the doped well 108 is doped. In the p-type buried channel MOSFET example, the channel covering surface region 110 may be p-doped with a p-type dopant at a concentration in a range from about 1.2×10¹⁸ cm⁻³ to about 3×10¹⁸ cm⁻³. e.g., heavily doped. The concentration of the dopant of the channel covering surface region 110 is greater than the concentration of the dopant of the doped well 108.

A gate dielectric layer 116 is over (e.g., possibly on) the top major surface of the semiconductor substrate 102. The gate dielectric layer 116 may be or include any appropriate dielectric material, such as an oxide, nitride, the like, or a combination thereof. For example, the gate dielectric layer 116 may be a gate oxide layer.

A gate electrode 118 is disposed over the gate dielectric layer 116. The gate electrode 118 may be or include any appropriate conductive material, such as polysilicon (e.g., doped polysilicon), metal (e.g., tungsten (W), aluminum (Al), titanium (Ti), tantalum (Ta), or the like), the like, or a combination thereof. In the p-type buried channel MOSFET example, the gate electrode 118 is or includes n-doped polysilicon. Further, in such examples, the n-doped polysilicon may be doped with an n-type dopant at a concentration in a range from about 1×10¹⁸ cm⁻³ to about 1×10²¹ cm⁻³, e.g., heavily to very heavily doped. The gate electrode 118 may be doped (e.g., n-type in a p-type buried channel MOSFET) to tune a work function of the semiconductor device 100. Doping the gate electrode 118 may facilitate depleting the top major surface of the semiconductor substrate 102 (e.g., depleting the channel covering surface region 110) in operation of the semiconductor device 100 such that a channel region underlying the gate electrode 118 may be formed at a depth away from the top major surface of the semiconductor substrate 102, thus forming a buried channel.

A first energy barrier modulation region 120 and a second energy barrier modulation region 122 are disposed in the semiconductor substrate 102, and more specifically, in the doped well 108 in the semiconductor substrate 102. The energy barrier modulation regions 120, 122 extend from the top major surface of the semiconductor substrate 102 into a depth in the doped well 108. In some examples, the energy barrier modulation regions 120, 122 extend to a depth of 50 nm or more (e.g., 60 nm or more), and more specifically, in a range from 50 nm to 150 nm, from the top major surface of the semiconductor substrate 102. The depth from the top major surface that the energy barrier modulation regions 120, 122 extend is greater than the depth from the top major surface that the channel covering surface region 110 extends. The energy barrier modulation regions 120, 122 underlie the gate dielectric layer 116 and the gate electrode 118. The energy barrier modulation regions 120, 122 are disposed on generally opposing sides (e.g., with a channel width direction bisecting between the energy barrier modulation regions 120, 122) relative to the gate dielectric layer 116 and the gate electrode 118. The channel covering surface region 110 is disposed laterally between the first energy barrier modulation region 120 and second energy barrier modulation region 122. The energy barrier modulation regions 120, 122 are doped with a dopant that has a conductivity type that is the same as the conductivity type of the dopant with which the doped well 108 is doped and that is counter to the conductivity type of the dopant with which the channel covering surface region 110 is doped. In the p-type buried channel MOSFET example, the energy barrier modulation regions 120, 122 may be n-doped with an n-type dopant at a concentration in a range from about 2.4×10¹⁸ cm⁻³ to about 5×10¹⁸ cm⁻³, e.g., heavily doped. The concentration of the dopant of the energy barrier modulation regions 120, 122 is greater than the concentration of the dopant of the channel covering surface region 110.

A first LDD region 124 and a second LDD region 126 are disposed in the semiconductor substrate 102, and more specifically, in the doped well 108 in the semiconductor substrate 102. The LDD regions 124, 126 extend from the top major surface of the semiconductor substrate 102 into a depth in the doped well 108. In some examples, the LDD regions 124, 126 extend to a depth of 50 nm or more (e.g., 75 nm or more), and more specifically, in a range from 50 nm to 150 nm, from the top major surface of the semiconductor substrate 102. The depth from the top major surface that the LDD regions 124, 126 extend is greater than the depth from the top major surface that the energy barrier modulation regions 120, 122 extend. The LDD regions 124, 126 generally are disposed laterally extending in opposite directions (e.g., with a channel width direction bisecting between the LDD regions 124, 126) from the gate dielectric layer 116 and the gate electrode 118. The first energy barrier modulation region 120 is disposed laterally between the channel covering surface region 110 and the first LDD region 124. The second energy barrier modulation region 122 is disposed laterally between the channel covering surface region 110 and the second LDD region 126. The LDD regions 124, 126 are doped with a dopant that has a conductivity type that is the same as the conductivity type of the dopant with which the channel covering surface region 110 is doped and that is counter to the conductivity type of the dopant with which the doped well 108 and energy barrier modulation regions 120, 122 are doped. In the p-type buried channel MOSFET example, the LDD regions 124, 126 may be p-doped with a p-type dopant at a concentration in a range from about 2.4×10¹⁸ cm⁻³ to about 5×10¹⁸ cm⁻³, e.g., heavily doped. The concentration of the dopant of the LDD regions 124, 126 is greater than the concentration of the dopant of the energy barrier modulation regions 120, 122.

A first gate spacer 130 and a second gate spacer 132 are disposed along respective sidewall surfaces of the gate electrode 118. The first gate spacer 130 is generally over the first LDD region 124, and the second gate spacer 132 is generally over the second LDD region 126. The gate spacers 130, 132 may be or include any appropriate dielectric material and/or multiple layers of materials, such as an oxide, a nitride, the like, or a combination thereof.

A source region 134 and a drain region 136 are disposed in the semiconductor substrate 102, and more specifically, in the doped well 108 in the semiconductor substrate 102. The source region 134 and drain region 136 extend from the top major surface of the semiconductor substrate 102 into a depth in the doped well 108. In some examples, the source region 134 and drain region 136 extend to a depth of 75 nm or more (e.g., 100 nm or more), and more specifically, in a range from 75 nm to 175 nm, from the top major surface of the semiconductor substrate 102. The depth from the top major surface that the source region 134 and the drain region 136 extend is greater than the depth from the top major surface that the LDD regions 124, 126 extend. The source region 134 and drain region 136 generally are disposed laterally extending in opposite directions (e.g., with a channel width direction bisecting between the source region 134 and the drain region 136) from the respective gate spacers 130, 132. The first LDD region 124 is disposed laterally between the first energy barrier modulation region 120 and the source region 134. The second LDD region 126 is disposed laterally between second energy barrier modulation region 122 and the drain region 136. The source region 134 and drain region 136 are doped with a dopant that has a conductivity type that is the same as the conductivity type of the dopant with which the LDD regions 124, 126 and the channel covering surface region 110 are doped and that is counter to the conductivity type of the dopant with which the doped well 108 and energy barrier modulation regions 120, 122 are doped. In the p-type buried channel MOSFET example, the source region 134 and drain region 136 may be p-doped with a p-type dopant at a concentration in a range from about 1×10¹⁹ cm⁻³ to about 1×10²¹ cm⁻³, e.g., heavily to very heavily doped. The concentration of the dopant of the source region 134 and drain region 136 is greater than the concentration of the dopant of the LDD regions 124, 126.

A backgate region 138 is disposed in the semiconductor substrate 102, and more specifically, in the doped well 108 in the semiconductor substrate 102. The backgate region 138 extends from the top major surface of the semiconductor substrate 102 into a depth in the doped well 108. The backgate region 138 is disposed proximate to the source region 134. The backgate region 138 is doped with a dopant that has a conductivity type that is the same as the conductivity type of the dopant with which the doped well 108 is doped and that is counter to the conductivity type of the dopant with which the source region 134 and drain region 136 are doped. In the p-type buried channel MOSFET example, the backgate region 138 may be n-doped with an n-type dopant at a concentration in a range from about 1×10¹⁹ cm⁻³ to about 1×10²¹ cm⁻³. e.g., heavily to very heavily doped.

A first dielectric layer 140 is disposed over the semiconductor substrate 102, the gate electrode 118, and gate spacers 130, 132. The first dielectric layer 140 is conformally over and on the semiconductor substrate 102, the gate spacers 130, 132, and the gate electrode 118. The first dielectric layer 140 may include one or more dielectric layers. For example, the first dielectric layer 140 may include a layer of silicon nitride (SiN) or the like. A second dielectric layer 142 is disposed over the first dielectric layer 140. The second dielectric layer 142 may be or include an inter-layer dielectric. The second dielectric layer 142 may be or include an oxide or the like.

A source contact 144 is disposed through the dielectric layers 140, 142 and electrically contacts the source region 134. A drain contact 146 is disposed through the dielectric layers 140, 142 and electrically contacts the drain region 136. A backgate contact 148 is disposed through the dielectric layers 140, 142 and electrically contacts the backgate region 138. The source contact 144, drain contact 146, and backgate contact 148 may include a metal-semiconductor compound (e.g., silicide) at the top major surface of the semiconductor substrate 102, one or more barrier and/or adhesion layers (e.g., titanium nitride (TiN), tantalum nitride (TaN), the like, or a combination thereof) conformally in a respective opening through the dielectric layers 140, 142, and a conductive fill material (e.g., a metal, such as tungsten (W), copper (Cu), a combination thereof, or the like) on the barrier and/or adhesion layer(s).

Metal lines 154, 156, 158 are disposed on an upper surface of the second dielectric layer 142 and electrically couple the source contact 144, drain contact 146, and backgate contact 148, respectively. The metal lines 154, 156, 158 may include one or more barrier and/or adhesion layers (e.g., titanium nitride (TiN), tantalum nitride (TaN), the like, or a combination thereof) and a conductive fill material (e.g., a metal, such as tungsten (W), copper (Cu), a combination thereof, or the like) on the barrier and/or adhesion layer(s).

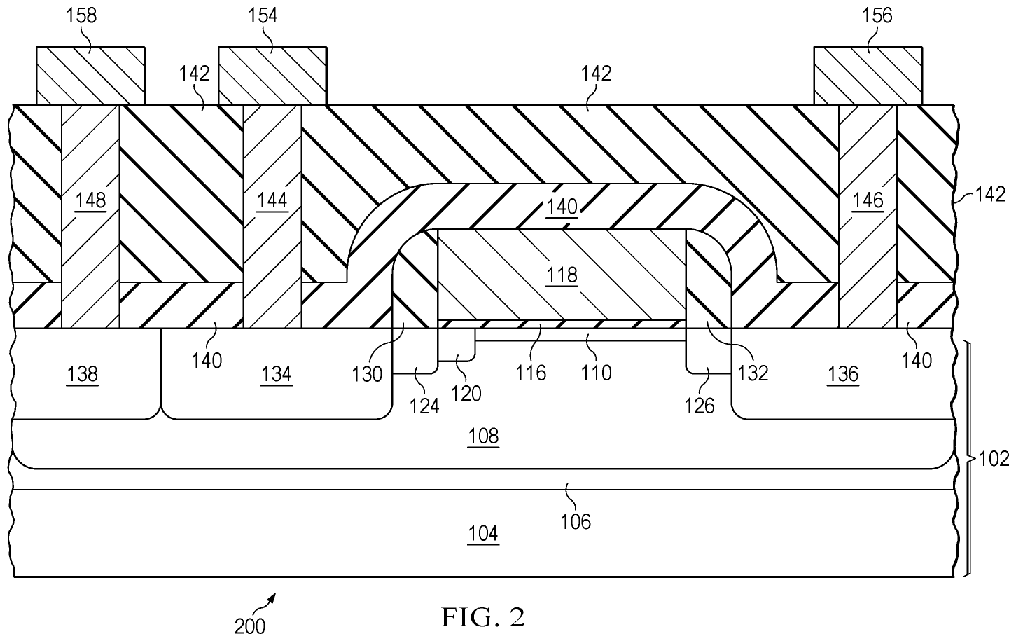

FIG. 2 is a cross-sectional view of a semiconductor device 200 according to some examples. The semiconductor device 200, in this example, is or includes a buried channel MOSFET. The buried channel MOSFET may be a p-type buried channel MOSFET, like described with respect to FIG. 1, and in other examples, the buried channel MOSFET may be an n-type buried channel MOSFET. The semiconductor device 200 of FIG. 2 is like the semiconductor device 100 of FIG. 1, except that the second energy barrier modulation region 122 is omitted. The channel covering surface region 110 extends laterally under the gate dielectric layer 116 to the second LDD region 126. The semiconductor device 200 of FIG. 2 is asymmetric with respect to the energy barrier modulation region around the width direction of the channel region of the semiconductor device 200.

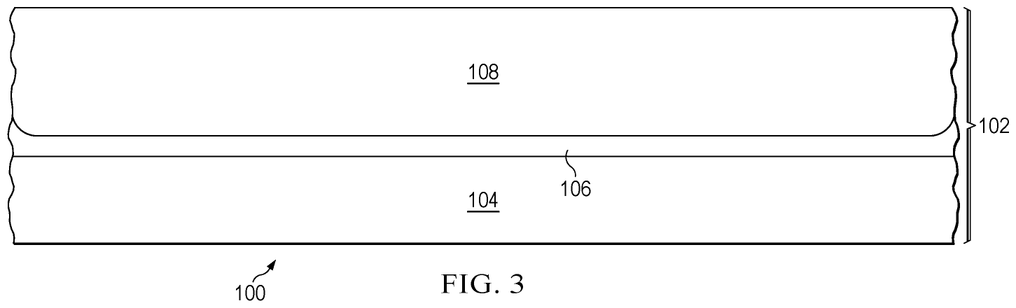

FIGS. 3 through 11 illustrate cross-sectional views of the semiconductor device 100 of FIG. 1 at various stages of manufacturing according to an example method. The method illustrated by FIGS. 3 through 11 may be modified to implement the semiconductor device 200 of FIG. 2. Such modifications are described subsequently.

Referring to FIG. 3, a semiconductor substrate 102 is provided. In providing the semiconductor substrate 102, an epitaxial layer 106 is formed over a semiconductor support substrate 104. The epitaxial layer 106 may be formed using an appropriate epitaxial growth process, such as low pressure chemical vapor deposition (LPCVD) or the like. In an example, the epitaxial layer 106 is silicon. The epitaxial layer 106 is doped, such as by in situ doping during the epitaxial growth. The dopant type and concentration of the epitaxial layer 106 are as described above. In the illustrated example, the semiconductor support substrate 104 and the epitaxial layer 106 form a semiconductor substrate 102. In other examples, another semiconductor substrate may be used. For example, the semiconductor substrate 102 may be a bulk silicon wafer (e.g., without the epitaxial layer 106) and may include a doped well implanted with a dopant type and concentration like the epitaxial layer 106.

A doped well 108 is formed in the semiconductor substrate 102 (e.g., in the epitaxial layer 106). The doped well 108 may be formed by implanting dopants into the epitaxial layer 106. A photolithography process may be used to mask areas of the semiconductor substrate 102 during the implantation. To mask an area(s), a photoresist may be deposited (e.g., by spin-on) over the semiconductor substrate 102 and patterned using photolithography. Once processing utilizing the mask (e.g., dopant implantation) is completed, the mask may be removed, such as by ashing. The dopant type and concentration of the doped well 108 are as described above.

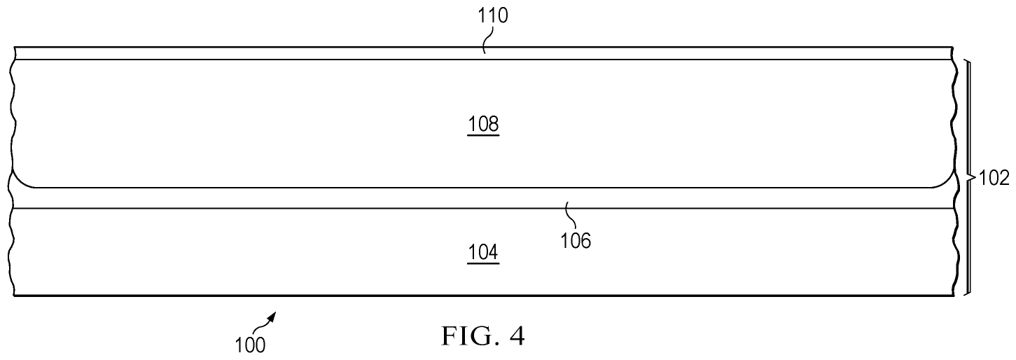

Referring to FIG. 4, a channel covering surface region 110 is formed in the semiconductor substrate 102 (e.g., in the epitaxial layer 106), and more particularly, in the doped well 108. The channel covering surface region 110 is formed at a top major surface of the semiconductor substrate 102. The channel covering surface region 110 may be formed by implanting dopants into the semiconductor substrate 102. A mask used to form the doped well 108 may further be used in forming the channel covering surface region 110. The dopant type and concentration of the channel covering surface region 110 are as described above.

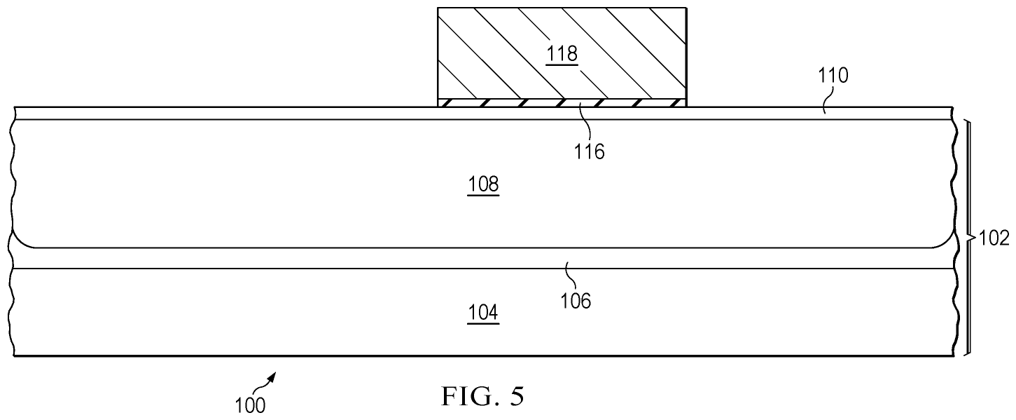

Referring to FIG. 5, a gate dielectric layer 116 is formed over the semiconductor substrate 102, and a gate electrode 118 is formed over the gate dielectric layer 116. A gate dielectric layer 116 may be formed or deposited across the top major surface of the semiconductor substrate 102, and material of the gate electrode 118 may deposited over the gate dielectric layer 116. The gate dielectric layer 116 may be any appropriate dielectric material and may be formed by an oxidation process or a deposition process, such as a chemical vapor deposition (CVD) or the like. The material of the gate electrode 118 may be or include, for example, polysilicon (e.g., doped polysilicon), metal, the like, or a combination thereof. In an example in which a p-type buried channel MOSFET is formed, the material of the gate electrode 118 deposited at FIG. 5 is polysilicon, which is n-doped. In such an example, the polysilicon may be doped by a blanket implant after deposition (e.g., before patterning the polysilicon) or by in situ doping during deposition. As apparent by subsequent description, the gate electrode 118 may further be implanted by various implantation processes (e.g., by using self-aligned techniques); however, in some examples, the concentration to which the polysilicon is doped with respect to FIG. 5 is a magnitude such that the subsequent implantations into the polysilicon do not dominate the dopant conductivity type to which the polysilicon is doped with respect to FIG. 5. The material of the gate electrode 118 may be deposited by any appropriate deposition process, such as CVD, physical vapor deposition (PVD), or the like. The material of the gate electrode 118 and the gate dielectric layer 116 are then patterned into the gate electrode 118 and gate dielectric layer 116 using appropriate photolithography and etching processes.

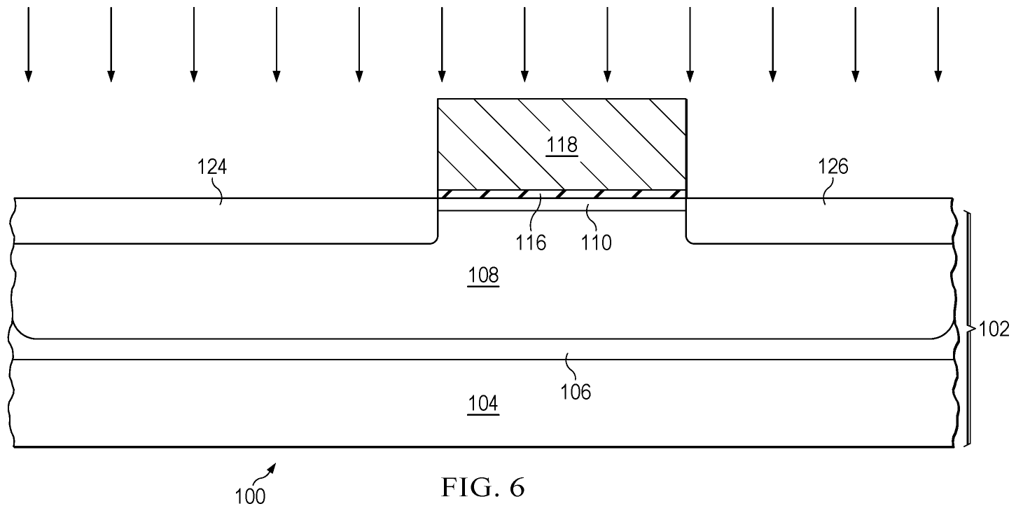

Referring to FIG. 6, a first LDD region 124 and a second LDD region 126 are formed in the semiconductor substrate 102 (e.g., in the epitaxial layer 106), and more particularly, in the doped well 108. The first LDD region 124 and second LDD region 126 are formed at the top major surface of the semiconductor substrate 102. The first LDD region 124 and second LDD region 126 may be formed by implanting dopants into the semiconductor substrate 102. The implantation may be performed by using implantations at complementary or symmetric angles. For example, a first implantation may be performed at a positive angle with respect to a normal of the major surface of the semiconductor substrate 102, and a second implantation may be performed at a negative angle (e.g., having a same magnitude as the positive angle) with respect to the normal of the major surface of the semiconductor substrate 102. In some examples, the complementary or symmetric angles may have a magnitude within five degrees from the normal. The gate electrode 118 may act as a mask to substantially prevent implantation into the semiconductor substrate 102 underlying the gate electrode 118 and to substantially align the LDD regions 124, 126 with respective sidewall surfaces of the gate electrode 118. In some examples, the gate electrode 118 may be implanted with dopants when the LDD regions 124, 126 are formed (e.g., in a self-aligned technique). The dopant type and concentration of the channel covering surface region 110 are as described above.

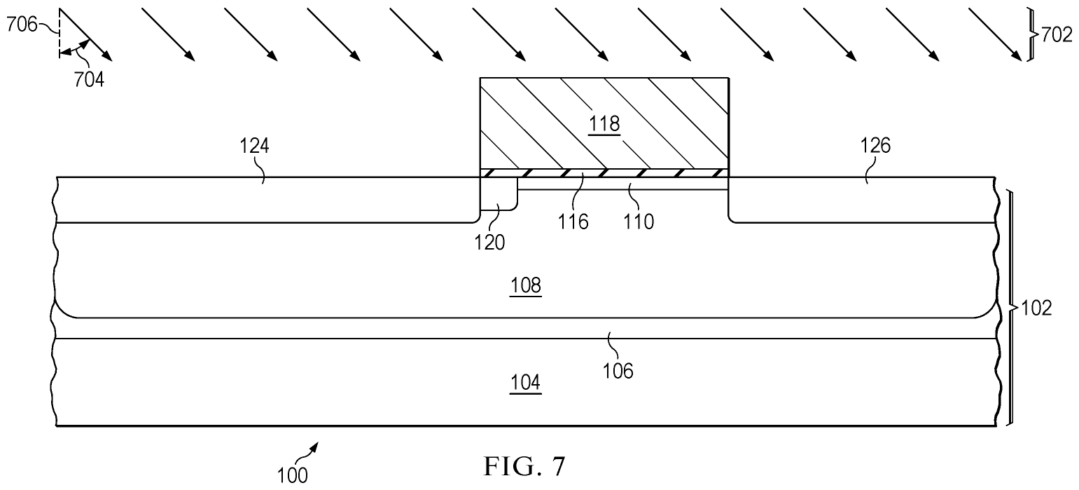

Referring to FIG. 7, a first energy barrier modulation region 120 is formed in the semiconductor substrate 102 (e.g., in the epitaxial layer 106), and more particularly, in the doped well 108. The first energy barrier modulation region 120 is formed at the top major surface of the semiconductor substrate 102 and underlying the gate electrode 118 and gate dielectric layer 116. The first energy barrier modulation region 120 may be formed by implanting 702 dopants into the semiconductor substrate 102. The implantation 702 may be performed at a first angle 704 relative to the normal 706 of the top major surface of the semiconductor substrate 102. In some examples, the first angle 704 may be in a range from +15 degrees to +60 degrees relative to the normal 706. In some examples, the first angle 704 is +45 degrees relative to the normal. The gate electrode 118 may act as a mask to substantially prevent implantation into the semiconductor substrate 102 where a shadow of the gate electrode 118 occurs. The dopant type and concentration of the first energy barrier modulation region 120 are as described above.

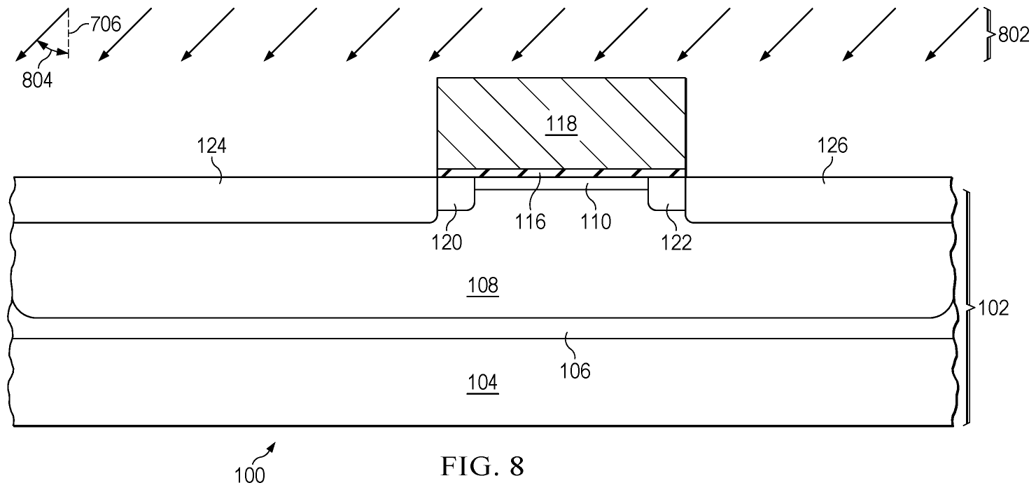

Referring to FIG. 8, a second energy barrier modulation region 122 is formed in the semiconductor substrate 102 (e.g., in the epitaxial layer 106), and more particularly, in the doped well 108. The second energy barrier modulation region 122 is formed at the top major surface of the semiconductor substrate 102 and underlying the gate electrode 118 and gate dielectric layer 116 opposite from the first energy barrier modulation region 120. The second energy barrier modulation region 122 may be formed by implanting 802 dopants into the semiconductor substrate 102. The implantation 802 may be performed at a second angle 804 relative to the normal 706 and complementary to the first angle 704 described with respect to FIG. 7. In some examples, the second angle 804 may be in a range from −15 degrees to −60 degrees relative to the normal 706. In some examples, the second angle 804 is −45 degrees relative to the normal 706. The gate electrode 118 may act as a mask to substantially prevent implantation into the semiconductor substrate 102 where a shadow of the gate electrode 118 occurs. The dopant type and concentration of the second energy barrier modulation region 122 are as described above. In examples where the semiconductor device 200 of FIG. 2 is to be formed, the processing of FIG. 8 may be omitted.

When the semiconductor device 100 (or semiconductor device 200) is fabricated in a complementary process (e.g., complementary MOS (CMOS) process), other areas of the semiconductor substrate 102 may be masked during the processing of FIGS. 6, 7, and 8. A same mask may be used to form the LDD regions 124, 126 and energy barrier modulation regions 120, 122. Hence, relative to CMOS processing in which energy barrier modulation regions 120, 122 are not formed, the semiconductor device 100 (or semiconductor device 200) may be fabricated without implementing an additional mask. In some examples, the implantation 702, 802 may correspond to n-type LDD implantation for n-type MOSFETs in the CMOS process. In such examples, the mask used for the n-type LDD implantation can be modified to open (e.g., uncover) the area including the semiconductor device 100 such that the semiconductor device 100 may be fabricated without implementing an additional mask or additional implantation steps.

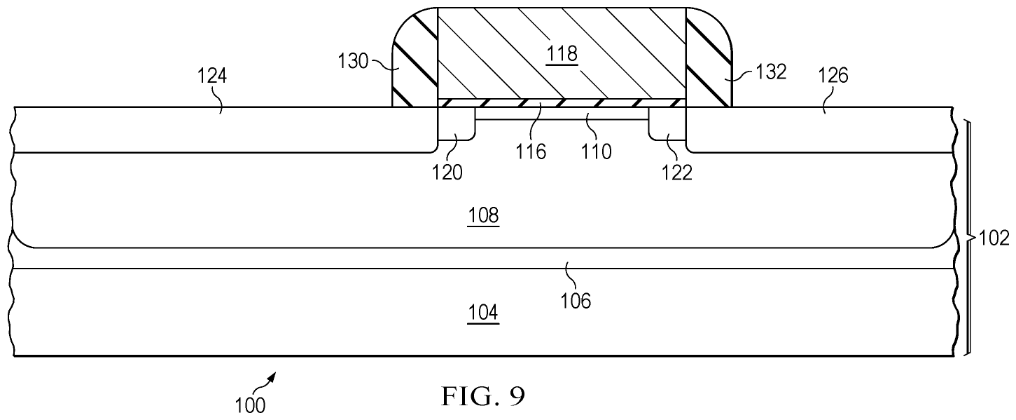

Referring to FIG. 9, gate spacers 130, 132 are formed along sidewall surfaces of the gate electrode 118. A material of gate spacers 130, 132 may be deposited on or over the semiconductor substrate 102 and gate electrode 118. The material of the gate spacers 130, 132 may be or include any appropriate dielectric materials, such as an oxide, a nitride, the like, or a combination thereof, and may be deposited using an appropriate deposition process, such as CVD, atomic layer deposition (ALD), or the like. The material of the gate spacers 130, 132 is then anisotropically etched, such as by a reactive ion etch (RIE), to remove substantially lateral portions and such that gate spacers 130, 132 remain on the sidewall surfaces of the gate electrode 118.

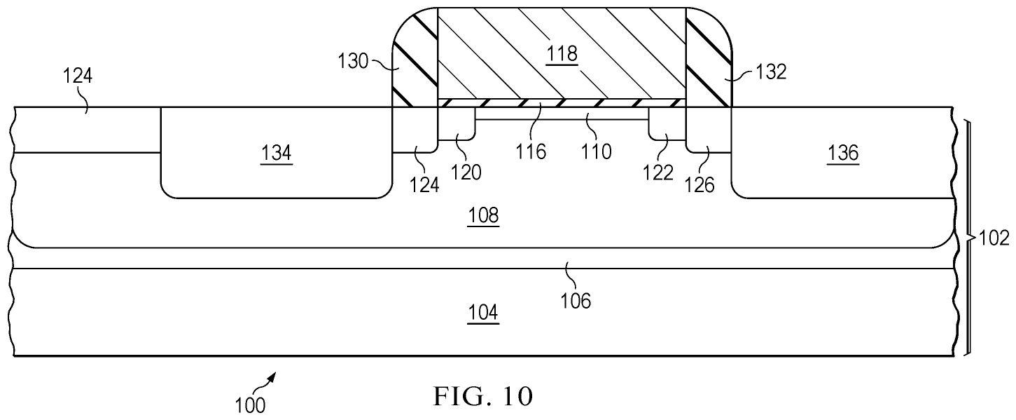

Referring to FIG. 10, a source region 134 and a drain region 136 are formed in the semiconductor substrate 102. The source region 134 and the drain region 136 may be formed by implanting dopants into the semiconductor substrate 102. Although not illustrated, a mask may be implemented to prevent areas of the semiconductor substrate 102 from being implanted with dopants during the formation of the source region 134 and the drain region 136. In some examples, the gate electrode 118 may be exposed through a mask during the implantation, and hence, the gate electrode 118 may be implanted with dopants when the source region 134 and drain region 136 are formed (e.g., in a self-aligned technique). Although the gate electrode 118 may be implanted in the formation of the source region 134 and drain region 136 in FIG. 10, and in the formation of the LDD regions 124, 126 in FIG. 6, in examples where the source region 134, drain region 136, and LDD regions 124, 126 are doped counter to the dopant of the gate electrode 118, the implantations that form the source region 134, drain region 136, and LDD regions 124, 126 do not change the conductivity type of the gate electrode 118 as doped with respect to FIG. 5. The dopant type and concentration of the source region 134 and drain region 136 are as described above.

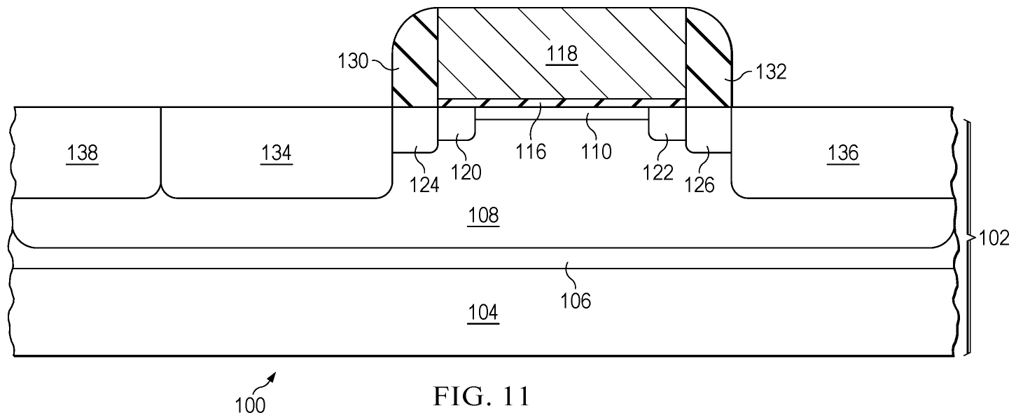

Referring to FIG. 11, a backgate region 138 is formed in the semiconductor substrate 102. The backgate region 138 may be formed by implanting dopants into the semiconductor substrate 102. The source region 134, drain region 136, and gate electrode 118 may be masked during the implantation to form the backgate region 138. The dopant type and concentration of the backgate region 138 are as described above.

Referring to FIG. 1 (or FIG. 2), a first dielectric layer 140 is formed over the semiconductor substrate 102, the gate electrode 118, and the gate spacers 130, 132. The first dielectric layer 140 may be conformally deposited over the semiconductor substrate 102, the gate electrode 118, and the gate spacers 130, 132. The first dielectric layer 140 may be or include any appropriate dielectric material and may be deposited by any appropriate deposition process, such as CVD or the like. A second dielectric layer 142 is formed over the first dielectric layer 140. The second dielectric layer 142 may be or include any appropriate dielectric material and may be deposited by any appropriate deposition process, such as CVD, PVD, or the like. The second dielectric layer 142 may be planarized, such as by a chemical mechanical polish (CMP) process.

A source contact 144, a drain contact 146, and a backgate contact 148 are formed through the dielectric layers 140, 142. Openings corresponding to the contacts 144, 146, 148 are formed through the dielectric layers 140, 142 using photolithography and etching processes. Respective openings expose respective source region 134, drain region 136, and backgate region 138. A barrier and/or adhesion layer may then be conformally deposited, such as by CVD, ALD, or the like, in the openings, and a fill metal may be deposited, such as by CVD, PVD, or the like, on the barrier and/or adhesion layer. Any barrier and/or adhesion layer and fill material on the top surface of the second dielectric layer 142 may be removed by a CMP, for example. Hence, each of the source contact 144, the drain contact 146, and the backgate contact 148 may include a barrier and/or adhesion layer and a fill metal. Further, in some examples, each of the source contact 144, the drain contact 146, and the backgate contact 148 may include a metal-semiconductor compound, such as by depositing a metal on the top major surface of the semiconductor substrate 102 where the source region 134, drain region 136, and backgate region 138 are disposed and reacting the metal with the semiconductor substrate 102 by using an anneal.

Metal lines 154, 156, 158 are formed over the second dielectric layer 142 and the source contact 144, drain contact 146, and backgate contact 148, respectively. Metal may be deposited over the second dielectric layer 142, the source contact 144, drain contact 146, and backgate contact 148 and patterned into the metal lines 154, 156, 158. The metal may include one or multiple metals deposited by any appropriate deposition process, such as CVD, PVD, or the like. The metal may be patterned into the metal lines 154, 156, 158 using appropriate photolithography and etching processes.

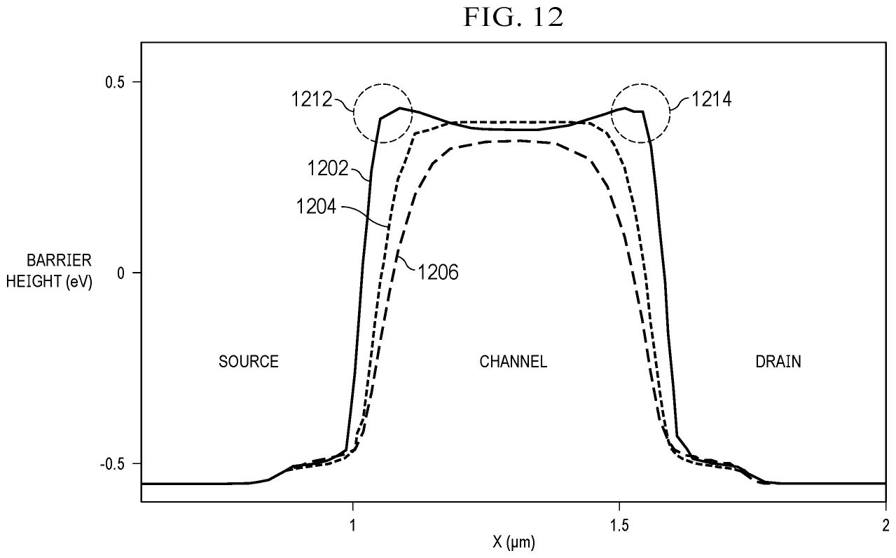

FIG. 12 is a chart illustrating energy barrier heights of different semiconductor devices. Energy barrier heights are shown as a function of lateral direction (e.g., x) parallel to a channel length direction and across a respective semiconductor device. Energy barrier height function 1202 shows the energy barrier height for a semiconductor device according to FIG. 1. Energy barrier height function 1204 shows the energy barrier height for a semiconductor device that is a surface channel device. Energy barrier height function 1206 shows the energy barrier height for a semiconductor device similar to FIG. 1, except without the energy barrier modulation regions 120, 122.

The energy barrier height function 1202 shows peaks 1212, 1214 proximate opposing sides of the channel region. The peaks 1212, 1214 cause a threshold voltage of the semiconductor device to be increased. For example, the energy barrier height function 1206 is lower throughout the channel region. Further, between the peaks 1212, 1214, the energy barrier height function 1202 is less than the energy barrier height function 1204 and is near the energy barrier height function 1206. This may permit the semiconductor device corresponding to the energy barrier height function 1202 (e.g., of FIG. 1) to operate like a similar semiconductor device (e.g., a buried channel semiconductor device) without the energy barrier modulation regions 120, 122.

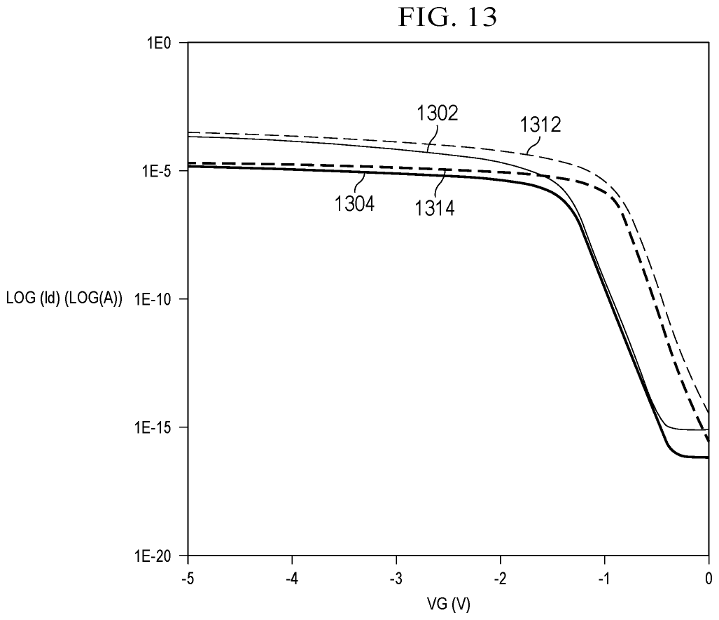

FIG. 13 is a chart illustrating simulated drain current (Id) curves for semiconductor devices. The chart of FIG. 13 shows the drain current (Id) curves for a first device according to FIG. 1 and for a second device similar to FIG. 1, except without the energy barrier modulation regions 120, 122. Both the first device and the second device were designed with a channel length of 0.7 μm and a channel width of 1 μm. Drain current curves 1302, 1304 are the drain current (Id) as a function of gate voltage (Vg) for the first device according to FIG. 1. Drain current curves 1312, 1314 are the drain current (Id) as a function of gate voltage (Vg) for the second device. Drain current curves 1302, 1312 show the drain current (Id) when a drain voltage (Vd) is equal to −5 V. Drain current curves 1304, 1314 show the drain current (Id) when a drain voltage (Vd) is equal to −0.1 V. As shown, the drain current curves 1302, 1304 of the first device drop at a higher magnitude gate voltage (Vg) compared to the drain current curves 1312, 1314 of the second device. This shows that the threshold voltage of the first device of FIG. 1 (e.g., as a magnitude) is greater than the threshold voltage of the second device without the energy barrier modulation regions 120, 122. Moreover, at a same gate voltage below the respective threshold voltages (e.g., at Vg=−0.6V), the first device exhibits drain current (e.g., off-state drain current) that is approximately five orders of magnitude less than the second device. Accordingly, as illustrated by this data, various examples may achieve increased threshold voltage and reduced leakage voltage.

Although various examples have been described in detail, it should be understood that various changes, substitutions, and alterations can be made therein without departing from the scope defined by the appended claims.

What is claimed is:

1. A semiconductor device comprising:
a first source/drain region in a doped region, the doped region being in a semiconductor substrate, the semiconductor substrate having an upper surface, the doped region being doped with a first conductivity type, the first source/drain region being doped with a second conductivity type opposite from the first conductivity type;
a first energy barrier modulation region in the doped region and at the upper surface of the semiconductor substrate, the first energy barrier modulation region being doped with the first conductivity type;
a channel covering surface region in the doped region and at the upper surface of the semiconductor substrate, the channel covering surface region being doped with the second conductivity type; and
a gate structure over the upper surface, the first energy barrier modulation region and the channel covering surface region underlying the gate structure, the first energy barrier modulation region being laterally between the first source/drain region and the channel covering surface region.

2. The semiconductor device of claim 1, wherein the gate structure includes polysilicon of the first conductivity type.

3. The semiconductor device of claim 1 further comprising a lightly doped drain (LDD) region in the doped region and extending laterally from the first source/drain region, the LDD region being doped with the second conductivity type, the LDD region being laterally between the first source/drain region and the first energy barrier modulation region.

4. The semiconductor device of claim 3 further comprising a gate spacer along a sidewall surface of the gate structure and over the upper surface of the semiconductor substrate, the LDD region underlying the gate spacer.

5. The semiconductor device of claim 1 further comprising a second source/drain region in the doped region, the second source/drain region being doped with the second conductivity type, the channel covering surface region being laterally between the first source/drain region and the second source/drain region.

6. The semiconductor device of claim 5, wherein no energy barrier modulation region doped with the first conductivity type is laterally between the second source/drain region and the channel covering surface region.

7. The semiconductor device of claim 5 further comprising a lightly doped drain (LDD) region in the doped region and extending laterally from the second source/drain region, the LDD region being doped with the second conductivity type, the LDD region being laterally between the second source/drain region and the channel covering surface region.

8. The semiconductor device of claim 1 further comprising:
a second source/drain region in the doped region, the second source/drain region being doped with the second conductivity type, the channel covering surface region being laterally between the first source/drain region and the second source/drain region; and
a second energy barrier modulation region in the doped region and at the upper surface of the semiconductor substrate, the second energy barrier modulation region being doped with the first conductivity type, the second energy barrier modulation region underlying the gate structure, the second energy barrier modulation region being laterally between the second source/drain region and the channel covering surface region.

9. The semiconductor device of claim 8 further comprising a lightly doped drain (LDD) region in the doped region and extending laterally from the second source/drain region, the LDD region being doped with the second conductivity type, the LDD region being laterally between the second source/drain region and the second energy barrier modulation region.

10. A method of forming a semiconductor device, the method comprising:
forming a channel covering surface region in a doped region in a semiconductor substrate and at an upper surface of the semiconductor substrate, the doped region being doped with a first conductivity type, the channel covering surface region being doped with a second conductivity type opposite from the first conductivity type;
forming a gate structure over the upper surface and over the channel covering surface region;
forming a first energy barrier modulation region in the doped region and at the upper surface of the semiconductor substrate, forming the first energy barrier modulation region including implanting a first dopant of the first conductivity type in the semiconductor substrate underlying the gate structure; and
forming a first source/drain region in the doped region, the first source/drain region being doped with the second conductivity type, the first energy barrier modulation region being laterally between the first source/drain region and the channel covering surface region.

11. The method of claim 10 further comprising forming a lightly doped drain (LDD) region in the doped region and at the upper surface of the semiconductor substrate, forming the LDD region including implanting a second dopant of the second conductivity type in the semiconductor substrate, the LDD region being laterally between the first source/drain region and the first energy barrier modulation region.

12. The method of claim 11 further comprising forming a gate spacer over the LDD region and along a sidewall surface of the gate structure.

13. The method of claim 11, wherein the implanting the first dopant of the first conductivity type and the implanting the second dopant of the second conductivity type are performed after the gate structure is formed.

14. The method of claim 11, wherein:
the implanting the first dopant of the first conductivity type is performed at a first angle from a normal direction relative to the upper surface of the semiconductor substrate, the first angle having a magnitude in a range from 15 degrees to 60 degrees; and
the implanting the second dopant of the second conductivity type is performed at a second angle from the normal direction, the second angle having a magnitude less than or equal to 5 degrees.

15. The method of claim 10 further comprising:
forming a second energy barrier modulation region in the doped region and at the upper surface of the semiconductor substrate, forming the second energy barrier modulation region including implanting a second dopant of the first conductivity type in the semiconductor substrate underlying the gate structure, the channel covering surface region being laterally between the first energy barrier modulation region and the second energy barrier modulation region; and
forming a second source/drain region in the doped region, the second source/drain region being doped with the second conductivity type, the second energy barrier modulation region being laterally between the second source/drain region and the channel covering surface region.

16. The method of claim 15, wherein:
implanting the first dopant of the first conductivity type in the semiconductor substrate underlying the gate structure is performed at a first angle from a normal direction relative to the upper surface of the semiconductor substrate; and
implanting the second dopant of the first conductivity type in the semiconductor substrate underlying the gate structure is performed at a second angle from the normal direction, the second angle being symmetric with the first angle relative to the normal direction.

17. The method of claim 16 further comprising forming a lightly doped drain (LDD) region in the doped region and at the upper surface of the semiconductor substrate, forming the LDD region including implanting a third dopant of the second conductivity type in the semiconductor substrate, the LDD region being laterally between the second source/drain region and the second energy barrier modulation region.

18. A semiconductor device comprising:
a first p-type source/drain region in an n-type well in a semiconductor substrate, the semiconductor substrate having an upper surface;
a first n-type region in the n-type well and at the upper surface of the semiconductor substrate;
a p-type region in the n-type well and at the upper surface of the semiconductor substrate; and
a gate structure over the upper surface, the first n-type region and the p-type region underlying the gate structure, the first n-type region being laterally between the first p-type source/drain region and the p-type region.

19. The semiconductor device of claim 18 further comprising a p-type lightly doped drain (LDD) region in the n-type well and extending laterally from the first p-type source/drain region, the p-type LDD region being laterally between the first p-type source/drain region and the first n-type region.

20. The semiconductor device of claim 19 further comprising a gate spacer along a sidewall surface of the gate structure and over the upper surface of the semiconductor substrate, the p-type LDD region underlying the gate spacer.

21. The semiconductor device of claim 18 further comprising:
a second p-type source/drain region in the n-type well, the p-type region being laterally between the first p-type source/drain region and the second p-type source/drain region; and
a second n-type region in the n-type well and at the upper surface of the semiconductor substrate, the second n-type region underlying the gate structure, the second n-type region being laterally between the second p-type source/drain region and the p-type region.

22. The semiconductor device of claim 21 further comprising a p-type lightly doped drain (LDD) region in the n-type well and extending laterally from the second p-type source/drain region, the p-type LDD being laterally between the second p-type source/drain region and the second n-type region.

23. The semiconductor device of claim 18, wherein the gate structure includes n-type polysilicon.
